(19) United States
(12) Patent Application Publication
(10) Pub. No.: US 2008/0029827 A1
(43) Pub. Date: Feb. 7, 2008

(54) Double gate transistor, method of manufacturing same, and system containing same

(76) Inventor: Ibrahim Ban, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/499,127

(22) Filed: Aug. 4, 2006

(51) Int. Cl. H01L 29/76; H01L 29/94; H01L 31/00

(52) U.S. Cl. 257/401

(57) ABSTRACT

A double gate transistor includes a substrate (110), a first semiconducting region (121) over the substrate, a second semiconducting region (122) adjacent to a first side of the first semiconducting region, and a third semiconducting region (123) adjacent to a second side of the first semiconducting region. The double gate transistor further includes a first electrically insulating layer (130) over the first semiconducting region, a second electrically insulating layer (140) over the first electrically insulating layer, a third electrically insulating layer (150) adjacent to the second semiconducting region, and a fourth electrically insulating layer (160) adjacent to the third semiconducting region. The double gate transistor still further comprises a first polysilicon region (170) adjacent to the third electrically insulating layer and a second polysilicon region (180) adjacent to the fourth electrically insulating layer.

### FIELD OF THE INVENTION

The disclosed embodiments of the invention relate generally to transistors, and relate more particularly to transistor charge storage.

### BACKGROUND OF THE INVENTION

Transistors are foundational devices of the semiconductor industry. One type of transistor, the field effect transistor (FET), has among its components gate, source, drain, and body terminals. A voltage applied between the gate and the source terminals generates an electric field that creates an “inversion channel” though which current can flow. Such current flow may be controlled by varying the magnitude of the applied voltage.

Many configurations and fabrication methods have been devised for transistor gate terminals (as well as for other transistor components). One such configuration is what is frequently called a double gate transistor, in which a transistor has two gates instead of a single gate. Another such configuration is what is often called a floating body cell, in which the body terminal of the transistor is not directly connected to a fixed potential. The floating body cell may have data written to it based on the accumulation of holes. Existing floating body cells, however, suffer from limited charge storage capacity, and this is true regardless of whether such cells are externally biased. Accordingly, there exists a need for a floating body cell structure capable of increasing charge storage capacity over existing limits, as well as a method of manufacturing such a structure.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a double gate transistor according to an embodiment of the invention;

FIG. 2 is a flowchart illustrating a method of manufacturing a double gate transistor according to an embodiment of the invention;

FIGS. 3-6 are cross-sectional views of a double gate transistor at particular points in a manufacturing process according to an embodiment of the invention;

FIG. 7 is an energy band diagram corresponding to a double gate transistor according to an embodiment of the invention; and

FIG. 8 is a schematic representation of a system containing a double gate transistor according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used.

### DETAILED DESCRIPTION OF THE DRAWINGS

In one embodiment of the invention, a double gate transistor comprises a substrate, a first semiconducting region located over the substrate and having a first side, a second side, and an upper surface, a second semiconducting region adjacent to the first side of the first semiconducting region, and a third semiconducting region adjacent to the second side of the first semiconducting region. The double gate transistor further comprises a first electrically insulating layer over the first semiconducting region, a second electrically insulating layer over the first electrically insulating layer, a third electrically insulating layer adjacent to the second semiconducting region, and a fourth electrically insulating layer adjacent to the third semiconducting region. The double gate transistor still further comprises a first polysilicon region adjacent to the third electrically insulating layer and a second polysilicon region adjacent to the fourth electrically insulating layer. The foregoing transistor configuration creates a potential well into which holes can flow for enhanced charge storage purposes, as will be explained in detail below.

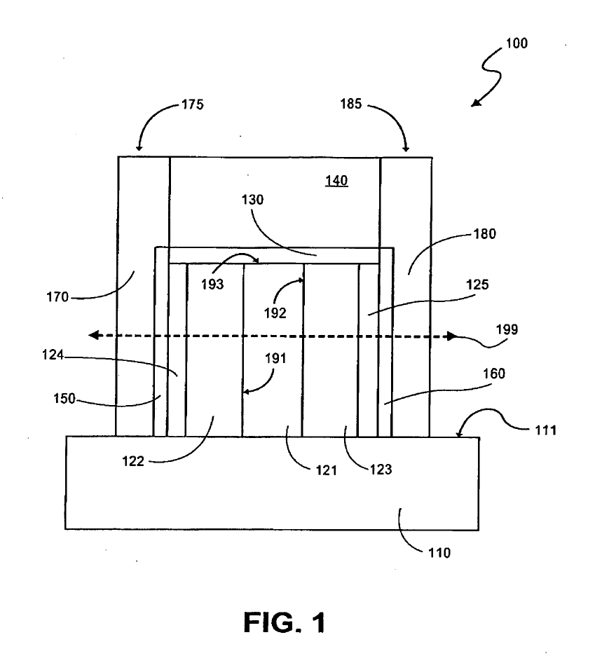

Referring now to the figures, FIG. 1 is a cross-sectional view of a double gate transistor 100 according to an embodiment of the invention. As illustrated in FIG. 1, double gate transistor 100 comprises a substrate 110 having a surface 111. Double gate transistor 100 further comprises a semiconducting region 121 having a side 191, a side 192 opposite side 191, and an upper surface 193, a semiconducting region 122 adjacent to side 191 of semiconducting region 121, and a semiconducting region 123 adjacent to side 192 of semiconducting region 121. An arrow 199 is a marker that will be discussed below in connection with a subsequent figure containing an energy band diagram for an embodiment of double gate transistor 100.

In one embodiment substrate 110 comprises a buried oxide layer such that double gate transistor 100 has a silicon-on-insulator (SOI) structure. In a different embodiment substrate 110 comprises a bulk silicon layer. A floating body cell construction on a bulk substrate will have substantially more leakage paths than will a floating body cell construction on an SOI substrate. However, the second gate in double gate transistor 100 attracts a substantial number of charge carriers that would otherwise wander freely, thus greatly improving charge storage and making such construction on bulk silicon a viable option.

In one embodiment semiconducting region 121 comprises silicon. In the same or another embodiment semiconducting region 122 and semiconducting region 123 comprise a material that has a band gap less than a band gap of silicon and is capable of being grown on silicon. As an example, the material can comprise silicon germanium (SiGe). The SiGe can be undoped or doped, graded or non-graded. In order to avoid defective films, the SiGe may need to be strained. In one embodiment, the SiGe is doped with boron atoms or another P-type material using in-situ doping techniques. Other materials having band gaps less than that of silicon and having discontinuities in the valence band may also be suitable for semiconducting regions 122 and 123.

Double gate transistor 100 further comprises an electrically insulating layer 130 over semiconducting region 121 and an electrically insulating layer 140 over electrically insulating layer 130. In one embodiment electrically insulating layer 140 comprises nitride or a nitride-based material or the like.

Double gate transistor 100 still further comprises an electrically insulating layer 150 adjacent to semiconducting region 122, an electrically insulating layer 160 adjacent to semiconducting region 123, a polysilicon region 170 adjacent to electrically insulating layer 150, and a polysilicon region 180 adjacent to electrically insulating layer 160. In one embodiment, polysilicon region 170 is part of a back gate 175 of double gate transistor 100 and polysilicon region 180 is part of a front gate 185 of double gate transistor 100. Advantageously, back gate 175 and front gate 185 may be controlled independently of each other.

In one embodiment electrically insulating layer 150 and electrically insulating layer 160 comprise silicon dioxide or the like. In a different embodiment electrically insulating layer 150 and electrically insulating layer 160 comprise a material having a high dielectric constant. (Such a material is referred to herein as a “high-k material.”) Silicon dioxide, which is currently widely used as a gate dielectric, has a dielectric constant (k) of approximately 3.9. Air, which is used as a scale reference point, has a dielectric constant defined as 1. Accordingly, any material having a dielectric constant greater than about 10 likely qualifies as, and is referred to herein as, a high-k material, a high-k film, a high-k dielectric, or a similar label that alludes to the relatively high dielectric constant of such material.

As an example, the high-k material used in an embodiment of double gate transistor 100 may be a hafnium-based, a zirconium-based, or a titanium-based dielectric material that may have a dielectric constant of at least approximately 20. In a particular embodiment the dielectric material is hafnium oxide having a dielectric constant of between approximately 20 and approximately 40. In a different particular embodiment the dielectric material is zirconium oxide having a dielectric constant of between approximately 20 and approximately 40.

In an embodiment where electrically insulating layers 150 and 160 comprise a high-k material, double gate transistor 100 further comprises a first metal layer (not shown) between electrically insulating layer 150 and polysilicon region 170, and also includes a second metal layer (not shown) between electrically insulating layer 160 and polysilicon region 180. As an example, the first and second metal layers can comprise tantalum nitride, titanium nitride, or the like.

As has already been seen, this disclosure makes reference to various kinds of “layers.” It should be understood that the word “layer” herein includes horizontally-oriented layers (layers having a major axis that is substantially parallel to surface 111 of substrate 110) and vertically-oriented layers (layers having a major axis that is substantially perpendicular to surface 111 of substrate 110), as well as layers having other orientations.

In one embodiment double gate transistor 100 still further comprises a semiconducting region 124 between semiconducting region 122 and electrically insulating layer 150, and a semiconducting region 125 between semiconducting region 123 and electrically insulating layer 160. As an example, semiconducting region 124 and semiconducting region 125 can comprise silicon. Semiconducting regions 124 and 125 are not required; however, their presence may improve the performance or simplify the manufacture of double gate transistor 100. For example, the quality of a gate oxide is generally much better on silicon than on other materials. If the gate dielectrics of electrically insulating layers 150 and 160 were formed directly on semiconducting regions 122 and 123 then the gate dielectric quality may suffer.

FIG. 1 depicts double gate transistor 100 following the completion of certain processing steps leading to its manufacture according to an embodiment of the invention. Subsequent figures, introduced and described below, depict double gate transistor 100 in various prior stages of manufacture, as will be discussed in greater detail below.

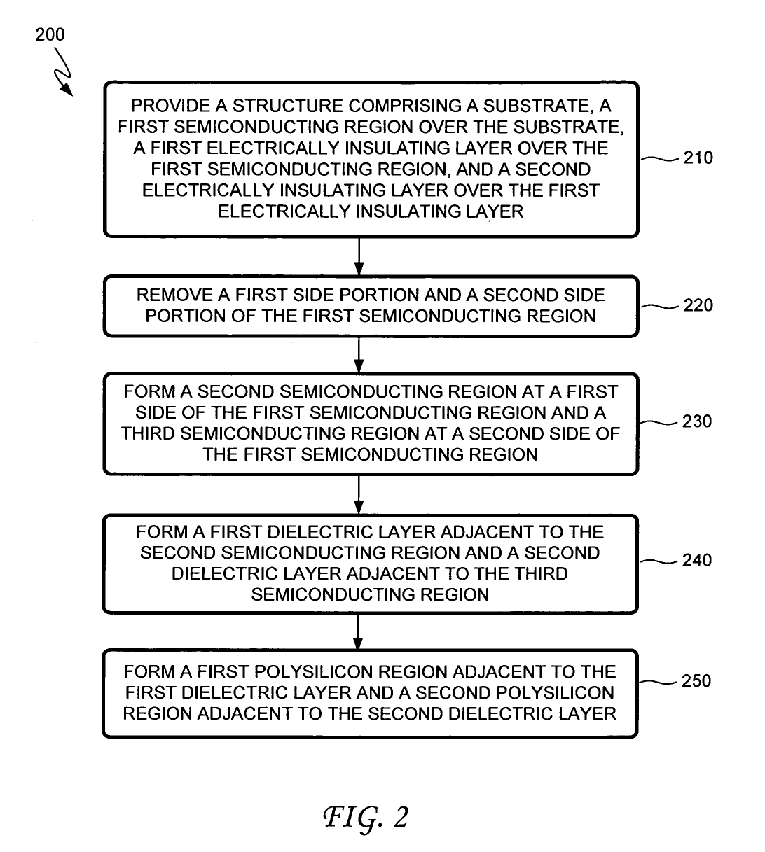

FIG. 2 is a flowchart illustrating a method 200 of manufacturing a double gate transistor according to an embodiment of the invention. A step 210 of method 200 is to provide a structure comprising a substrate, a first semiconducting region over the substrate, a first electrically insulating layer over the first semiconducting region, and a second electrically insulating layer over the first electrically insulating layer. As an example, the substrate, the first semiconducting region, the first electrically insulating layer, and the second electrically insulating layer can be similar to, respectively, substrate 110, semiconducting region 121, electrically insulating layer 130, and electrically insulating layer 140, all of which were first shown in FIG. 1.

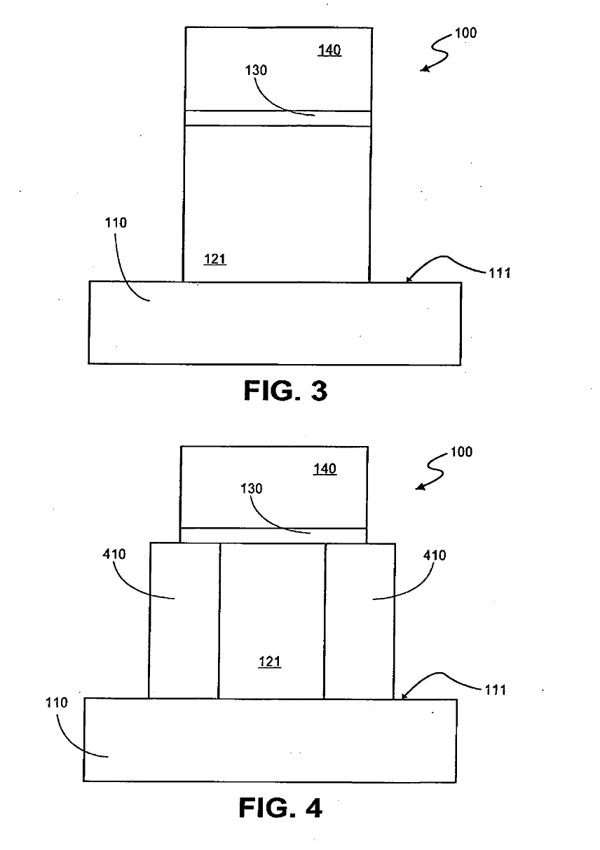

Substrate 110 (with surface 111), semiconducting region 121, and electrically insulating layers 130 and 140 are also shown in FIG. 3, which is a cross-sectional view of double gate transistor 100 at a particular point in method 200 or another manufacturing process according to an embodiment of the invention. FIG. 3 depicts double gate transistor 100 following trench formation, which may be accomplished according to processes known in the art.

A step 220 of method 200 is to remove a first side portion and a second side portion of the first semiconducting region. In one embodiment step 220 comprises consuming the first side portion and the second side portion using thermal oxidation. In that embodiment, method 200 can further comprise removing an oxide produced by the thermal oxidation. As an example, the grown oxide may be removed by etching it away with a hydrofluoric acid (HF)-based wet chemistry or the like.

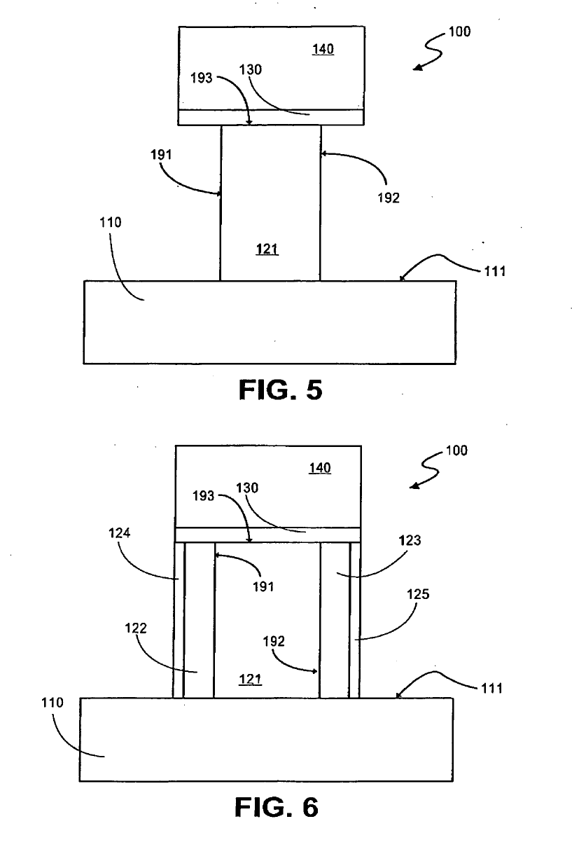

FIGS. 4 and 5 are cross-sectional views of double gate transistor 100 at particular points in method 200 or another manufacturing process according to an embodiment of the invention. FIG. 4 shows double gate transistor 100 during a thermal oxidation process during which a grown oxide 410 is used to consume semiconducting region 121 laterally on both sides. As an example, the grown oxide can be silicon dioxide or the like. FIG. 5 depicts double gate transistor 100 after grown oxide 410 has been removed. Sides 191 and 192 and upper surface 193 of semiconducting region 121 are also indicated in FIG. 5.

A step 230 of method 200 is to form a second semiconducting region at a first side of the first semiconducting region and a third semiconducting region at a second side of the first semiconducting region. (In at least one embodiment, step 230 is performed following one or more preclean steps, which steps may be carried out according to processes known in the art.) As an example, the second semiconducting region and the third semiconducting region can be similar to, respectively, semiconducting region 122 and semiconducting region 123, both of which were first shown in FIG. 1. Accordingly, in one embodiment, step 230 can comprise growing first and second SiGe layers on the sidewalls of the silicon body, i.e., on the sidewalls of the first semiconducting region.

In one embodiment, step 230 or another step comprises forming a fourth semiconducting region adjacent to the second semiconducting region and forming a fifth semiconducting region adjacent to the third semiconducting region. As an example, the fourth semiconducting region and the fifth semiconducting region can be similar to, respectively, semiconducting region 124 and semiconducting region 125, both of which were first shown in FIG. 1. Accordingly, in one embodiment, step 230 can comprise depositing first and second silicon cap layers on the sidewalls of the SiGe layers, i.e., on the sidewalls of the second and third semiconducting regions. Semiconducting regions 122, 123, 124, and 125 are also shown in FIG. 6, which is a cross-sectional view of double gate transistor 100 at a particular point in method 200 or another manufacturing process according to an embodiment of the invention.

In one embodiment, step 230, including the formation of each of semiconducting regions 122, 123, 124, and 125, can be performed while double gate transistor 100 is contained within a single tool or chamber. In other words, in one embodiment, a wafer containing double gate transistor 100 is placed inside a chamber and a chemistry capable of growing SiGe layers is introduced, followed by the introduction of a chemistry capable of depositing silicon layers. The two chemistries are similar enough to each other that the wafer need not be removed from the chamber prior to the change in chemistries.

A step 240 of method 200 is to form a first dielectric layer adjacent to the second semiconducting region and a second dielectric layer adjacent to the third semiconducting region. As an example, the first dielectric layer and the second dielectric layer can be similar to, respectively, electrically insulating layer 150 and electrically insulating layer 160, both of which were first shown in FIG. 1. Accordingly, in one embodiment step 240 comprises forming first and second silicon dioxide layers and in another embodiment comprises forming first and second layers containing both a high-k material and a metal region. In the latter embodiment, step 240 comprises forming regions of high-k material adjacent to semiconducting regions 124 and 125 (or adjacent to semiconducting regions 122 and 123 if semiconducting regions 124 and 125 are omitted), and forming metal regions adjacent to the regions of high-k material such that the high-k material is between the metal region and the corresponding semiconducting region. The metal regions are not explicitly illustrated or numbered in FIG. 1, but can be thought of as occupying an inside portion of electrically insulating layer 150 and 160 such that they are adjacent to semiconducting regions 124 and 125 (or to semiconducting regions 122 and 123 if semiconducting regions 124 and 125 are omitted).

A step 250 of method 200 is to form a first polysilicon region adjacent to the first dielectric layer and a second polysilicon region adjacent to the second dielectric layer. As an example, the first polysilicon region and the second polysilicon region can be similar to, respectively, polysilicon region 170 and polysilicon region 180, both of which were first shown in FIG. 1. In one embodiment, step 250 completes or advances the formation of back gate 175 and front gate 185 of double gate transistor 100. Polysilicon polishing, patterning, and further processing steps may proceed according to techniques that are known in the art.

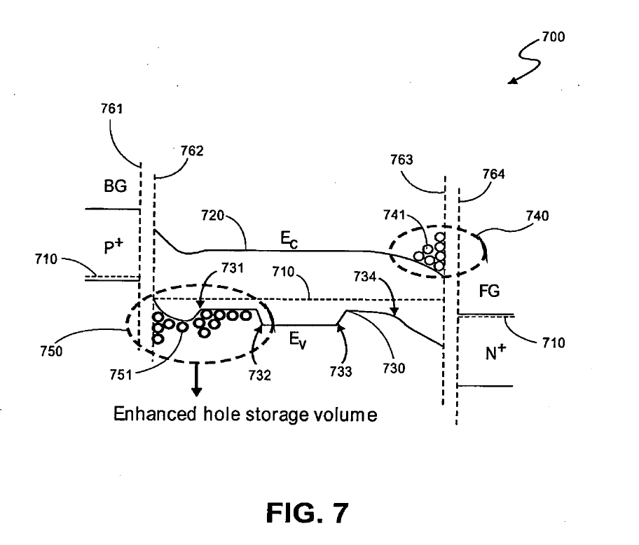

FIG. 7 is a graph 700 displaying an energy band diagram corresponding to double gate transistor 100 according to an embodiment of the invention. Graph 700 is an energy band diagram across a physical dimension of double gate transistor 100. Accordingly, the horizontal axis of graph 700 represents a physical dimension of double gate transistor 100 that corresponds to arrow 199 in FIG. 1, and the vertical axis of graph 700 represents the energy. The energy band diagram of graph 700 is valid for a condition in which a back gate is in an accumulated, hold state for the floating body cell and in which a front gate is in an inverted, write state for the floating body cell.

A dotted line 710 represents the Fermi level for graph 700. (Note that if there were no external bias on double gate transistor 100 the Fermi level would be a horizontal line across the entire x-dimension.) A line 720 represents the conduction band energy, and a line 730 represents the valence band energy. As known in the art, electrons tend to accumulate in areas of low energy along the conduction band and holes tend to accumulate in areas of high energy along the valence band. These phenomena are illustrated in graph 700, where a potential well 740 contains electrons 741 and a storage volume 750 contains holes 751.

Graph 700 further comprises a line 761, a line 762, a line 763, and a line 764. Lines 761 and 762, located near the left-hand side of graph 700 adjacent to the back gate (labeled “BG” in graph 700), represent boundaries of electrically insulating layer 150 in FIG. 1. Similarly, lines 763 and 764, located near the right-hand side of graph 700 adjacent to the front gate (labeled “FG” in graph 700), represent boundaries of electrically insulating layer 160 in FIG. 1.

As indicated, storage volume 750 represents an enhanced hole storage volume due to the presence of semiconducting regions 122 and 123, as will now be explained in more detail. Valence band Eᵥ (line 730) contains a number of segments that are bounded by numbered points along line 730 in graph 700. A first segment of line 730, representing the valence band in semiconducting region 124, stretches between line 762 and point 731. A second segment of line 730, representing the valance band in semiconducting region 122, stretches between point 731 and point 732. A third segment of line 730, representing the valance band in semiconducting region 121, stretches between point 732 and point 733. A fourth segment of line 730, representing the valance band in semiconducting region 123, stretches between point 733 and point 734. A fifth segment of line 730, representing the valance band in semiconducting region 125, stretches between point 734 and line 763.

In one embodiment, and with reference to FIGS. 1 and 7, double gate transistor 100 may be operated in the following manner. A positive voltage may be applied to front gate 185, thus creating potential well 740 to which electrons are attracted, as in the inversion condition for a typical metal-oxide semiconductor field effect transistor (MOSFET). When a bias is applied between the source and drain terminals a current flow is established between those two terminals. At high enough bias, impact ionization creates electron-hole pairs. Electrons generated by this impact ionization will flow out of the drain terminal, whereas holes will be pushed into the body of the transistor, thus creating excess positive charge. The greater the number of excess holes, the greater the ability of double gate transistor 100 to hold a charge. Thus the enhanced hole storage volume of embodiments of double gate transistor 100 directly increases charge retention time, i.e., directly increases the ability of the body terminal of double gate transistor 100 to hold a “1” state.

The presence of an additional gate—back gate 175—provides an additional opportunity to increase charge retention time by attracting additional holes to storage volume 750. This may be done by applying an additional bias (a negative voltage) to back gate 175. Alternatively, a lower voltage may be applied, yet the number of holes attracted may be kept roughly the same as in the front-gate-bias case described above.

As graph 700 clearly shows, the valence band at the second segment of line 730, where the SiGe is located, is higher than the valence band at the third segment where the original silicon is located. Because holes are attracted to and tend to accumulate in such higher energy areas, storage volume 750, and double gate transistor 100, have an ability to store holes that is enhanced over the storage ability of existing transistors.

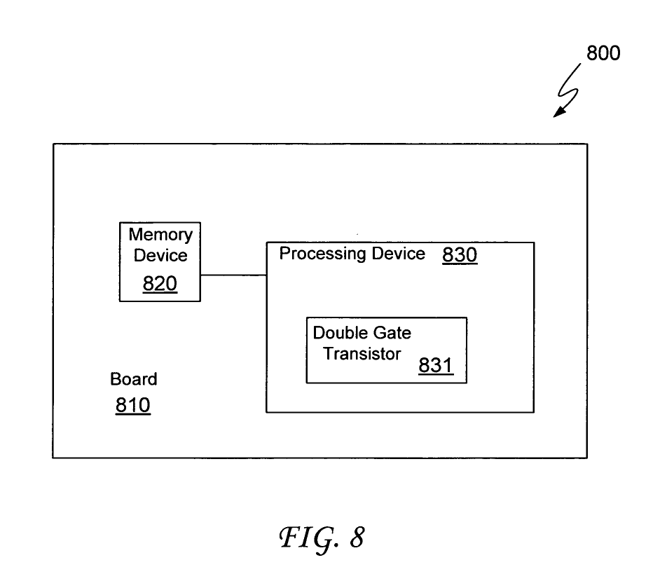

FIG. 8 is a schematic representation of a system 800 containing a double gate transistor according to an embodiment of the invention. As illustrated in FIG. 8, system 800 comprises a board 810, a memory device 820 disposed on board 810, and a processing device 830 disposed on board 810 and coupled to memory device 820. Processing device 830 comprises a double gate transistor 831 that comprises a substrate, a first semiconducting region located over the substrate and having a first side, a second side, and an upper surface, a second semiconducting region adjacent to the first side of the first semiconducting region, a third semiconducting region adjacent to the second side of the first semiconducting region, a first electrically insulating layer over the first semiconducting region, a second electrically insulating layer over the first electrically insulating layer, a third electrically insulating layer adjacent to the second semiconducting region, a fourth electrically insulating layer adjacent to the third semiconducting region, a first polysilicon region adjacent to the third electrically insulating layer, and a second polysilicon region adjacent to the fourth electrically insulating layer. As an example, double gate transistor 831 can be similar to double gate transistor 100, first shown in FIG. 1.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the double gate transistor and corresponding method and system discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A double gate transistor comprising:
a substrate;
a first semiconducting region over the substrate and having a first side, a second side, and an upper surface;
a second semiconducting region adjacent to the first side of the first semiconducting region;
a third semiconducting region adjacent to the second side of the first semiconducting region;
a first electrically insulating layer over the first semiconducting region;
a second electrically insulating layer over the first electrically insulating layer;
a third electrically insulating layer adjacent to the second semiconducting region;
a fourth electrically insulating layer adjacent to the third semiconducting region;
a first polysilicon region adjacent to the third electrically insulating layer; and
a second polysilicon region adjacent to the fourth electrically insulating layer.

2. The double gate transistor of claim 1 wherein:
the first polysilicon region comprises a back gate of the double gate transistor; and
the second polysilicon region comprises a front gate of the double gate transistor.

3. The double gate transistor of claim 1 wherein:
the first semiconducting region comprises silicon.

4. The double gate transistor of claim 3 wherein:
the second semiconducting region and the third semiconducting region comprise a material that:
has a band gap less than a band gap of silicon; and
is capable of being grown on silicon.

5. The double gate transistor of claim 4 wherein:
the material comprises silicon germanium.

6. The double gate transistor of claim 1 further comprising:
a fourth semiconducting region between the second semiconducting region and the third electrically insulating layer; and
a fifth semiconducting region between the third semiconducting region and the fourth electrically insulating layer.

7. The double gate transistor of claim 6 wherein:
the fourth semiconducting region and the fifth semiconducting region comprise silicon.

8. The double gate transistor of claim 1 wherein:
the third electrically insulating layer and the fourth electrically insulating layer comprise silicon dioxide.

9. The double gate transistor of claim 1 wherein:
the third electrically insulating layer and the fourth electrically insulating layer comprise a high-k material; and
the double gate transistor further comprises a first metal layer adjacent to the third electrically insulating layer and a second metal layer adjacent to the fourth electrically insulating layer.

10. The double gate transistor of claim 1 wherein:
the second electrically insulating layer comprises nitride.

11. The double gate transistor of claim 1 wherein:
the substrate comprises a buried oxide layer.

12. The double gate transistor of claim 1 wherein:
the substrate comprises a bulk silicon layer.

13. A method of manufacturing a double gate transistor, the method comprising:
providing a structure comprising:
a substrate;
a first semiconducting region over the substrate;
a first electrically insulating layer over the first semiconducting region; and
a second electrically insulating layer over the first electrically insulating layer;
removing a first side portion and a second side portion of the first semiconducting region;
forming a second semiconducting region at a first side of the first semiconducting region and forming a third semiconducting region at a second side of the first semiconducting region;
forming a first dielectric layer adjacent to the second semiconducting region and forming a second dielectric layer adjacent to the third semiconducting region; and
forming a first polysilicon region adjacent to the first dielectric layer and forming a second polysilicon region adjacent to the second dielectric layer.

14. The method of claim 13 wherein:
providing the structure comprises providing a first silicon layer as the first semiconducting region.

15. The method of claim 14 wherein:
forming the second semiconducting region and forming the third semiconducting region comprise forming layers comprising a material having a band gap less than a band gap of silicon and that is capable of being grown on silicon.

16. The method of claim 15 wherein:
forming layers comprising a material having a band gap less than a band gap of silicon and that is capable of being grown on silicon comprises forming layers comprising silicon germanium.

17. The method of claim 14 further comprising:
forming a fourth semiconducting region adjacent to the second semiconducting region; and
forming a fifth semiconducting region adjacent to the third semiconducting region.

18. The method of claim 17 wherein:
forming the second semiconducting region comprises forming a first silicon germanium layer;
forming the third semiconducting region comprises forming a second silicon germanium layer;
forming the fourth semiconducting region comprises forming a second silicon layer; and
forming the fifth semiconducting region comprises forming a third silicon layer.

19. The method of claim 18 wherein:
forming the second semiconducting region and forming the third semiconducting region comprises using a chamber to contain the double gate transistor;
forming the fourth semiconducting region and forming the fifth semiconducting region comprises using the chamber; and
the double gate transistor is not removed from the chamber between a formation of the second and third semiconducting regions and of the fourth and fifth semiconducting regions.

20. The method of claim 14 wherein:
forming the first dielectric layer comprises forming a first silicon dioxide layer; and
forming the second dielectric layer comprises forming a second silicon dioxide layer.

21. The method of claim 14 wherein:
forming the first dielectric layer comprises forming a first high-k material;
forming the second dielectric layer comprises forming a second high-k material; and
the method further comprises:
forming a first metal region adjacent to the first high-k material; and
forming a second metal region adjacent to the second high-k material.

22. The method of claim 14 wherein:
removing the first side portion and the second side portion of the first semiconducting region comprises consuming the first side portion and the second side portion using thermal oxidation.

23. The method of claim 22 further comprising:
removing an oxide produced by the thermal oxidation.

24. A system comprising:
a board;
a memory device disposed on the board; and
a processing device disposed on the board and coupled to the memory device, where the processing device includes a double gate transistor comprising:
a substrate;
a first semiconducting region over the substrate and having a first side, a second side, and an upper surface;
a second semiconducting region adjacent to the first side of the first semiconducting region;
a third semiconducting region adjacent to the second side of the first semiconducting region;
a first electrically insulating layer over the first semiconducting region;
a second electrically insulating layer over the first electrically insulating layer;
a third electrically insulating layer adjacent to the second semiconducting region;
a fourth electrically insulating layer adjacent to the third semiconducting region;
a first polysilicon region adjacent to the third electrically insulating layer; and
a second polysilicon region adjacent to the fourth electrically insulating layer.

25. The system of claim 24 wherein:
the first semiconducting region comprises silicon.

26. The system of claim 25 wherein:
the second semiconducting region and the third semiconducting region comprise silicon germanium.

27. The system of claim 26 further comprising:
a fourth semiconducting region between the second semiconducting region and the third electrically insulating layer; and
a fifth semiconducting region between the third semiconducting region and the fourth electrically insulating layer.

28. The system of claim 27 wherein:
the fourth semiconducting region and the fifth semiconducting region comprise silicon.
